(19) United States
(12) Patent Application Publication
(10) Pub. No.: US 2018/0019154 A1
(43) Pub. Date: Jan. 18, 2018

(54) SUBSTRATE TRANSFER ROBOT AND SUBSTRATE TRANSFER METHOD

(71) Applicant: KAWASAKI JUKOGYO KABUSHIKI KAISHA, Kobe-shi, Hyogo (JP)

(72) Inventors: Masaya YOSHIDA, Himeji-shi (JP); Masayuki SAITO, Akashi-shi (JP)

(73) Assignee: KAWASAKI JUKOGYO KABUSHIKI KAISHA, Kobe-shi, Hyogo (JP)

(21) Appl. No.: 15/548,739

(22) PCT Filed: Feb. 1, 2016
(86) PCT No.: PCT/JP2016/052951

§ 371 Date: Aug. 3, 2017

(30) Foreign Application Priority Data
Feb. 3, 2015 (JP) 2015-019201

(51) Int. Cl. H01L 21/687; H01L 21/67; B25J 13/08

(52) U.S. Cl. CPC H01L 21/68707; B25J 13/08; H01L 21/67259

(57) ABSTRACT

This substrate transfer robot includes: a robot arm to which a substrate holding portion for holding a substrate is movably provided; a robot control unit for controlling each operation of the robot arm and the substrate holding portion; and a substrate detection unit provided to the robot arm and for detecting an edge portion of the substrate held by the substrate holding portion. The substrate detection unit detects at least two parts of the edge portion of the substrate when the substrate holding portion is moved with respect to the robot arm. The robot control unit corrects a substrate transfer operation based on a detection result of the edge portion of the substrate. Thus, even when a substrate held by a substrate holding portion is deviated from a regular position, the substrate can be transferred without difficulty.

### TECHNICAL FIELD

The present invention relates to a substrate transfer robot comprising a substrate holding portion for holding a substrate and a robot arm to which the substrate holding portion is movably provided, and to a substrate transfer method using the robot.

### BACKGROUND ART

Conventionally, a substrate transfer robot is used as a means for transferring a substrate such as a semiconductor wafer. The substrate transfer robot comprises, for example, an articulated robot arm and a hand (substrate holding portion) provided to a distal end of this robot arm.

As for the hand of the substrate transfer robot, for example, there are a type for gripping and fixing an edge portion of a substrate (wafer) placed on the hand by an edge grip and a type for vacuum sacking and fixing the back surface of the substrate placed on the hand. In the case of the hand of the edge grip type, when gripping the substrate by the edge grip, a position of the substrate with respect to the hand is automatically adjusted to a regular position.

While, in the case of the hand of the vacuum sacking type, if the substrate is placed on the hand in a state of being deviated from a regular position, the position of the substrate is not adjusted to the regular position when vacuum sacking the substrate, and the substrate is fixed to the hand remaining in the state of being deviated from the regular position.

If the robot arm is driven and the substrate is transferred in the state of being deviated from the regular position as above, there are problems that the substrate collides with a container wall when the substrate is carried into a substrate container such as a FOUP or that the substrate cannot be exactly transferred to a target position when transferring the substrate to a substrate processor.

Accordingly, conventionally, the substrate which has been vacuum sacked by the hand is temporarily placed on an aligner and the position of the substrate is detected and position correction is performed utilizing the aligner, for example.

Additionally, other than the position correction method utilizing the aligner, a method is proposed wherein a sensor for detecting the substrate is installed on the device side and the deviation of the substrate on the hand is detected utilizing the sensor so as to perform position correction (Patent Document 1).

### CITATION LIST

### Patent Document

[Patent Document 1] Japanese Patent Application Laid-Open No. H10-223732

### SUMMARY OF INVENTION

### Objects to be Achieved by the Invention

However, in the above-mentioned position correction method utilizing the aligner, there is a problem that operation processes of the robot increase since special operations for performing position correction need to be performed by the robot. Additionally, in the case of a device which does not comprise the aligner, this position correction method cannot be originally performed. Further, in the method of arranging the sensor on the device side for detecting the substrate, there is a problem that the device configuration is complicated and the production cost is increased.

The present invention is made considering the above-mentioned problems of the conventional technology, and its object is to provide a substrate transfer robot and a substrate transfer method capable of transferring substrates without difficulty without using the aligner and the devise side sensor even when the substrate held by the substrate holding portion is deviated from the regular position.

### Means for Achieving the Objects

In order to achieve the above-mentioned objects, a substrate transfer robot according to a first aspect of the present invention comprises: a substrate holding portion for holding a substrate; a robot arm to which the substrate holding portion is movably provided; a robot control unit for controlling each operation of the robot arm and the substrate holding portion; and a substrate detection unit provided to the robot arm and for detecting an edge portion of the substrate held by the substrate holding portion, wherein the substrate detection unit is configured to detect at least two parts of the edge portion of the substrate when the substrate holding portion holding the substrate is moved with respect to the robot arm, and wherein the robot control unit is configured to correct a substrate transfer operation based on a detection result of the edge portion of the substrate by the substrate detection unit.

A second aspect of the present invention is that, in the first aspect, the robot arm has a first link member including a first rotational axis on a base end thereof and also including a second rotational axis on a distal end thereof, and a second link member including the second rotational axis on a base end thereof and also including a third rotational axis on a distal end thereof, wherein the substrate holding portion is rotatable about the third rotational axis, and wherein the substrate detection unit is provided to at least one of the first link member and the second link member.

A third aspect of the present invention is that, in the first or second aspect, the substrate detection unit is provided to a surface of a link member configuring the robot arm.

A fourth aspect of the present invention is that, in any one of the first to third aspects, the substrate detection unit has a plurality of substrate detection sensors.

A fifth aspect of the present invention is that, in any one of the first to fourth aspects, the substrate detection unit is configured to detect the edge portion of the substrate during a normal transfer operation of the substrate.

A sixth aspect of the present invention is that, in any one of the first to fifth aspects, the substrate detection unit includes a reflection type light sensor.

In order to achieve the above-mentioned objects, a seventh aspect of the present invention is a substrate transfer method using a substrate transfer robot having a robot arm to which a substrate holding portion for holding a substrate is movably provided, comprising: a holding step of holding the substrate by the substrate holding portion; a transfer step of transferring the substrate held by the substrate holding portion to a target position; a detection step of detecting at least two parts of an edge portion of the substrate during the transfer step using a substrate detection unit provided to the robot arm; and a correction step of correcting a substrate transfer operation based on a detection result of the edge portion of the substrate in the detection step.

An eighth aspect of the present invention is that, in the seventh aspect, in the detection step, the edge portion of the substrate is detected during a rotational operation of the substrate holding portion with respect to the robot arm.

A ninth aspect of the present invention is that, in the seventh or eighth aspect, in the detection step, the edge portion of the substrate is detected using the substrate detection unit provided to a surface of a link member configuring the robot arm.

A tenth aspect of the present invention is that, in any one of the seventh to ninth aspects, in the detection step, the edge portion of the substrate is detected using a reflection type light sensor configuring the substrate detection unit.

### Effect of the Invention

According to the present invention, even when a substrate held by a substrate holding portion is deviated from a regular position, the substrate can be transferred without difficulty without using an aligner and a devise side sensor.

### BRIEF DESCRIPTION OF THE DRAWINGS

FIG. 1 is a schematic view illustrating a substrate transfer robot according to one embodiment of the present invention.

FIG. 2 is a schematic plan view illustrating a substrate transfer operation of the substrate transfer robot in FIG. 1.

FIG. 3 is another schematic plan view illustrating a substrate transfer operation of the substrate transfer robot in FIG. 1.

FIG. 4 is a schematic plan view illustrating a substrate detection process in the substrate transfer robot in FIG. 1.

FIG. 5 is another schematic plan view illustrating the substrate detection process in the substrate transfer robot in FIG. 1.

FIG. 6 is a schematic plan view illustrating the substrate detection process in the case when the substrate is deviated from the regular position in the substrate transfer robot in FIG. 1.

FIG. 7 is another schematic plan view illustrating the substrate detection process in the case when the substrate is deviated from the regular position in the substrate transfer robot in FIG. 1.

FIG. 8 is another schematic plan view illustrating the substrate detection process in the case when the substrate is deviated from the regular position in the substrate transfer robot in FIG. 1.

FIG. 9 is another schematic plan view illustrating the substrate detection process in the case when the substrate is deviated from the regular position in the substrate transfer robot in FIG. 1.

FIG. 10 is a schematic plan view illustrating the substrate detection process in the case when the substrate is deviated from the regular position in a variation of the substrate transfer robot in FIG. 1.

FIG. 11 is another schematic plan view illustrating the substrate detection process in the case when the substrate is deviated from the regular position in a variation of the substrate transfer robot in FIG. 1.

FIG. 12 is a schematic view illustrating another variation of the substrate transfer robot in FIG. 1.

### EMBODIMENT OF THE INVENTION

Hereunder, a substrate transfer robot according to one embodiment of the present invention will be described referring to the drawings. Note that the substrate transfer robot according to this embodiment is suitable for transferring a circular substrate such as wafer for semiconductor manufacturing.

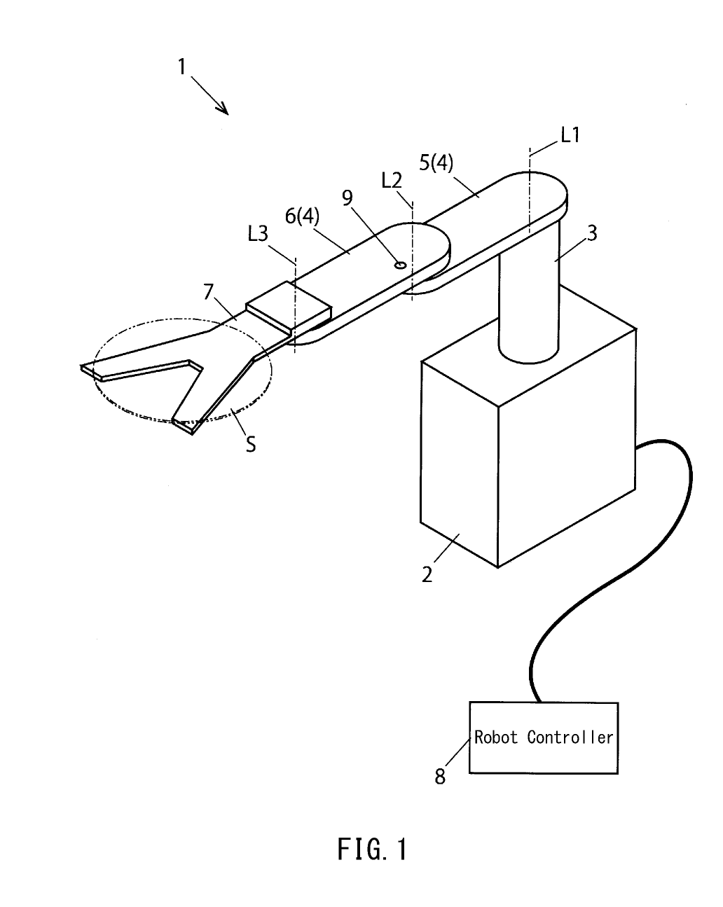

As illustrated in FIG. 1, a substrate transfer robot 1 according to this embodiment has a base 2. A rotary spindle 3 is provided to the base 2 so as to be elevated/lowered along a first rotational axis L1.

A robot arm 4 is connected to the upper end of the rotary spindle 3. The robot arm 4 has a first link member 5 including the first rotational axis L1 on the base end thereof and also including a second rotational axis L2 on the distal end thereof, and a second link member 6 including the second rotational axis L2 on the base end thereof and also including a third rotational axis L3 on the distal end thereof.

A hand (substrate holding portion) 7 is provided to the distal end of the second link member 6 so as to rotate about the third rotational axis L3. The hand 7 is configured to hold a substrate S by vacuum suction.

Control of the elevating/lowering operation of the rotary spindle 3, the rotational operation of each link member of the robot arm 4, and the rotational operation of the hand 7 is performed by controlling each servo motor which provides drive force for their operation by a robot controller 8.

Additionally, the substrate transfer robot 1 according to this embodiment comprises a substrate detection sensor (substrate detection unit) 9 on the upper surface of the second link member 6 of the robot arm 4. The substrate detection sensor 9 is a reflection type light sensor which omits light upward.

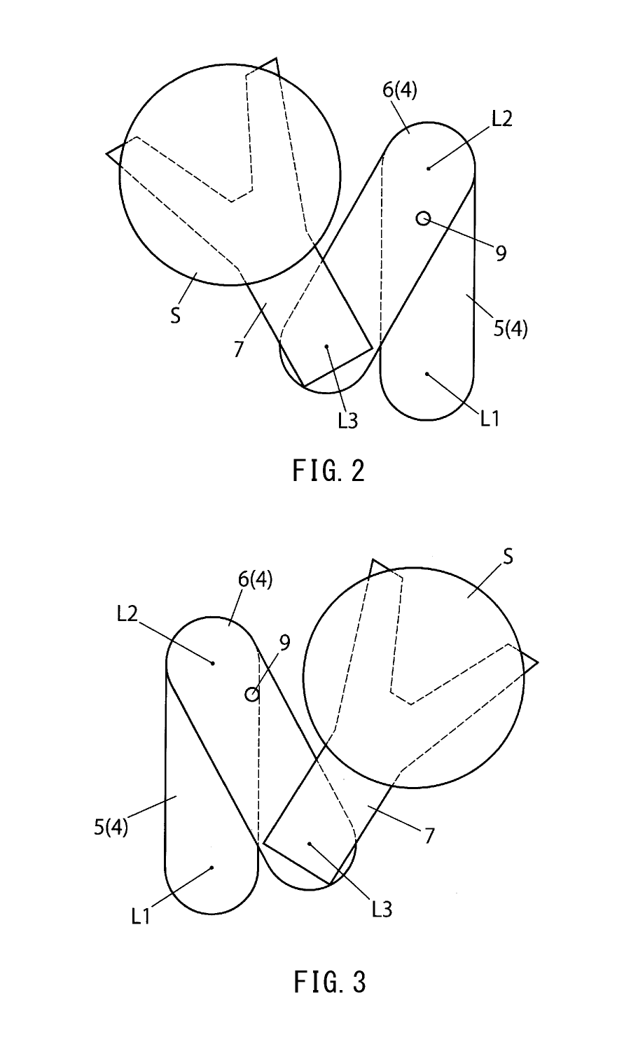

FIG. 2 and FIG. 3 illustrate a normal substrate transfer operation by the substrate transfer robot 1. The substrate S held by the hand 7 passes above the substrate detection sensor 9 provided to the robot arm 4, when the robot arm 4 is changed from the state in FIG. 2 to the state in FIG. 3

Additionally, in the states in FIG. 2 and FIG. 3, the substrate S does not exist above the substrate detection sensor 9, and therefore a detection signal of the substrate detection sensor 9 which is a reflection type light sensor is off.

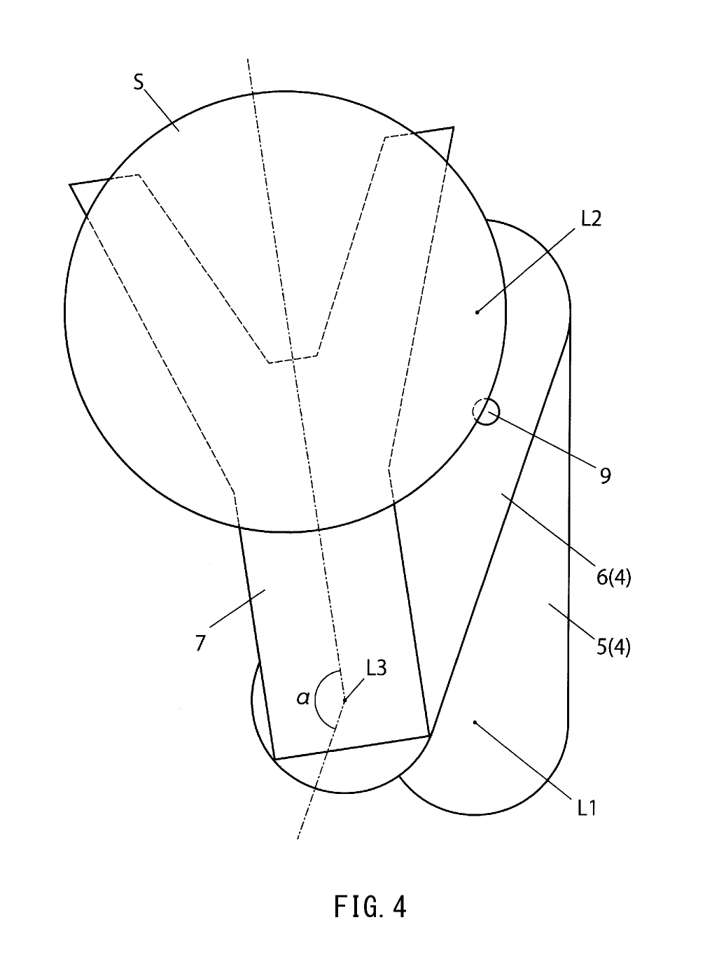

Note that, when the hand 7 is rotated about the third rotational axis L3 with respect to the second link member 6 from the state in FIG. 2, it becomes the state in FIG. 4 before becoming the state in FIG. 3. In the state in FIG. 4, an edge portion of the substrate S (front edge in moving direction) just passes above the substrate detection sensor 9, and therefore the detection signal of the substrate detection sensor 9 is changed from off to on at this moment. This point is referred to as a front edge passing point, and a rotation angle of the hand 7 about the third rotational axis L3 at this time is assumed to be α.

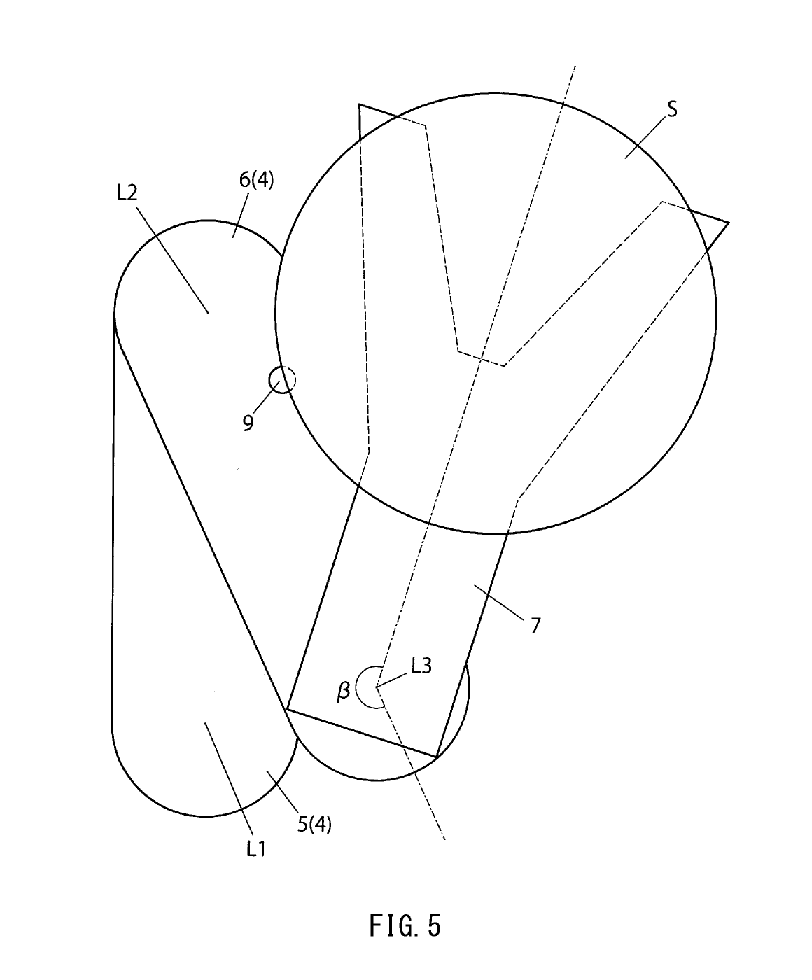

After the hand 7 is further rotated with respect to the second link member 6 about the third rotational axis L3 from the state in FIG. 4, it becomes the state in FIG. 5. In the state in FIG. 5, an edge portion of the substrate S (rear edge in moving direction) just passes above the substrate detection sensor 9, and therefore the detection signal of the substrate detection sensor 9 is changed from on to off at this moment. This point is referred to as a rear edge passing point, and a rotation angle of the hand about the third rotational axis L3 at this time is assumed to be β.

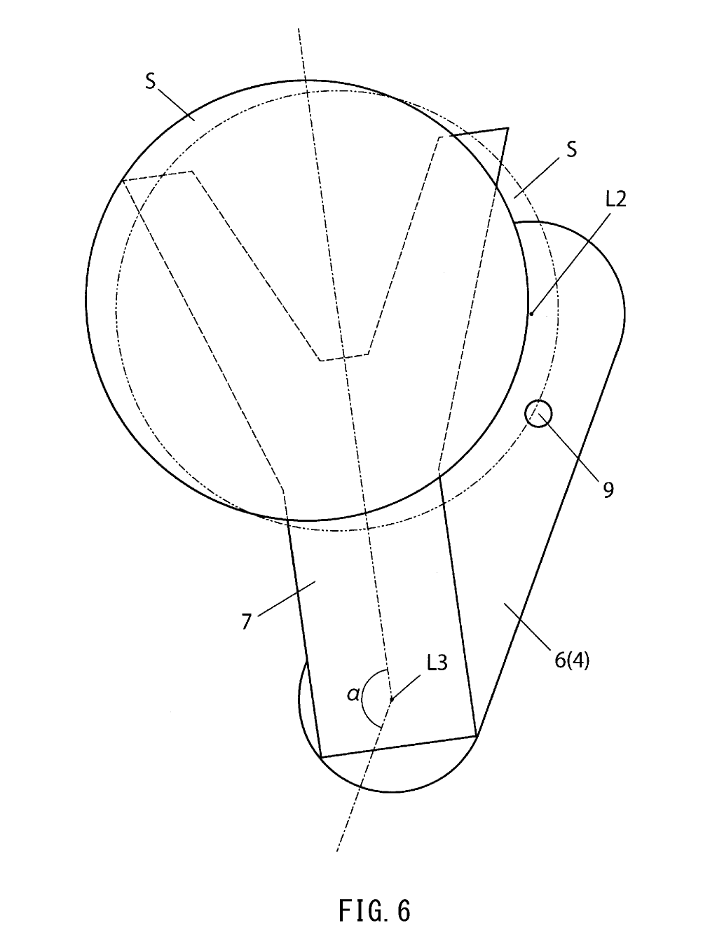

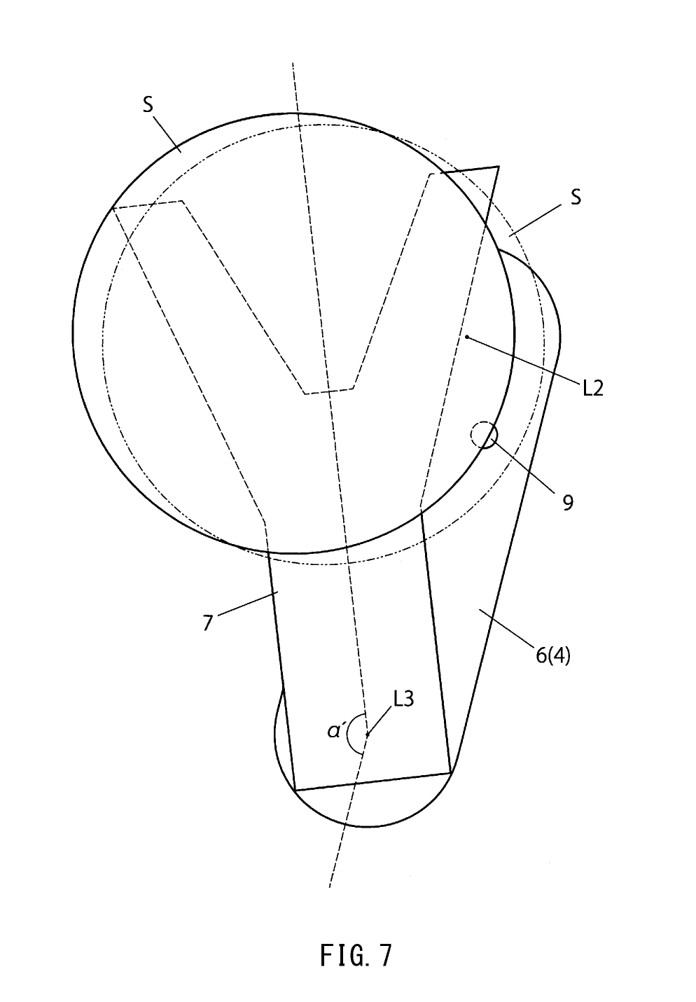

Next, the case when the substrate S held on the hand 7 is deviated from a regular position on the hand 7 will be described referring to FIG. 6 and FIG. 7.

First, the robot arm 4 and the hand 7 are driven by the robot controller 8 so as to place the substrate S on the hand 7, and sucking and holding the same (holding process). At this time, the substrate S on the hand 7 is assumed to be deviated from the regular position. Subsequently, the robot controller 8 further drives the robot arm 4 and the hand 7 so as to start a normal transfer operation for transferring the substrate S to a target position (transfer process).

FIG. 6 illustrates, in this transfer process, a point when the rotation angle of the hand 7 about the third rotational axis L3 is α, namely the front edge passing point in the case when the substrate S is held in the regular position (position of the substrate S illustrated by the virtual line) on the hand 7. As seen in FIG. 6, since the substrate S is deviated from the regular position on the hand 7, the edge portion (front edge in moving direction) of the substrate S does not reach above the substrate detection sensor 9 although the rotation angle of the hand 7 reaches α.

Since the substrate detection sensor 9 is not switched from off to on although the rotation angle of the hand 7 about the third rotational axis L3 reaches α, the robot controller 8 determines that the substrate S is deviated from the regular position on the hand 7.

When the hand 7 is further rotated about the third rotational axis L3 from the state in FIG. 6, the edge portion of the substrate S (front edge in moving direction) just passes above the substrate detection sensor 9 as illustrated in FIG. 7, and the detection signal of the substrate detection sensor 9 is changed from off to on (front edge detection process). The rotation angle of the hand 7 about the third rotational axis L3 at this point is assumed to be α′ and thus α′>α.

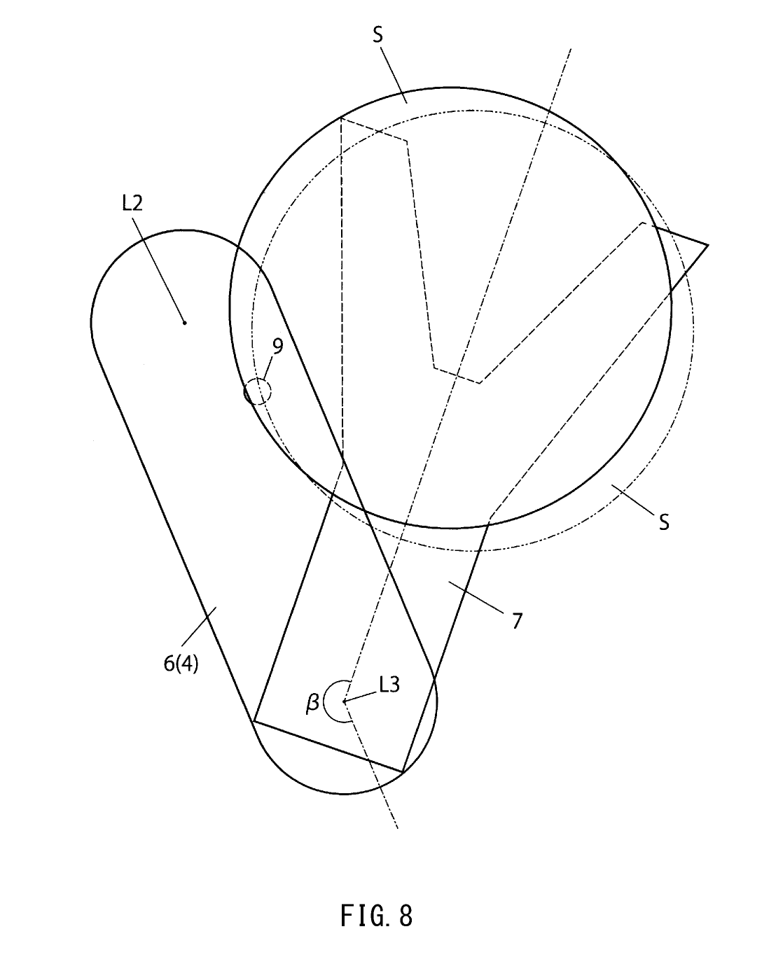

FIG. 8 illustrates the case when the rotation angle of the hand 7 about the third rotational axis L3 is β, namely the rear edge passing point in the case when the substrate S is held in the regular position (position of the substrate S illustrated by the virtual line) on the hand 7. As seen in FIG. 8, since the substrate S is deviated from the regular position on the hand 7, the edge portion (rear edge in moving direction) of the substrate S does not reach above the substrate detection sensor 9 although the rotation angle of the hand 7 reaches β.

Since the substrate detection sensor 9 is not switched from on to off although the rotation angle of the hand 7 about the third rotational axis L3 reaches β, the robot controller 8 determines that the substrate S is deviated from the regular position on the hand 7.

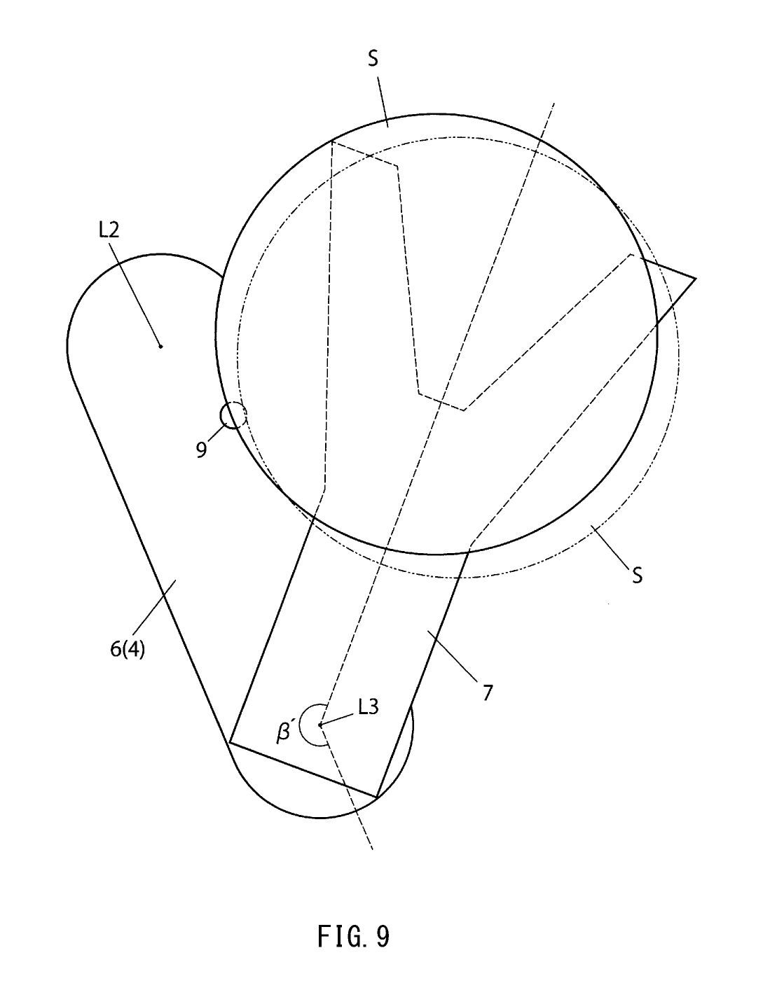

When the hand 7 is further rotated about the third rotational axis L3 from the state in FIG. 8, the edge portion of the substrate S (rear edge in moving direction) just passes above the substrate detection sensor 9 as illustrated in FIG. 9, and the detection signal of the substrate detection sensor 9 is changed from on to off (rear edge detection process). The rotation angle of the hand 7 about the third rotational axis L3 at this point is assumed to be β′ and thus β′>β.

Note that, depending on the deviation direction and deviation amount of the substrate S from the regular position, either one of the above-mentioned front edge detection and rear edge detection may be detected at the same angle as the normal rotation angle α, β. However, both the front edge detection and rear edge detection are never detected at the normal rotation angles α, β. Accordingly, except when both the front edge detection and rear edge detection are detected at the normal rotation angles α, β, the substrate S is determined to be deviated from the regular position on the hand 7.

The robot controller 8 specifies two positions of the edge portion of the substrate S on the hand 7 based on the hand rotation angel α′ upon the front edge detection in FIG. 7 and the hand rotation angle β upon the rear edge detection in FIG. 9. Since the edge portion of the substrate S forms a circle, by specifying two positions on the circumference, the position of the substrate S on the hand 7 can be specified using a known substrate diameter.

Then, the robot controller 8 corrects each operation of the robot arm 4 and the hand 7 in the transfer process thereafter, based on the actual position of the substrate S on the hand 7 which has been specified as above (correction process). Thereby, the substrate S can be exactly transferred to the target position even when the substrate S is deviated from the regular position on the hand 7.

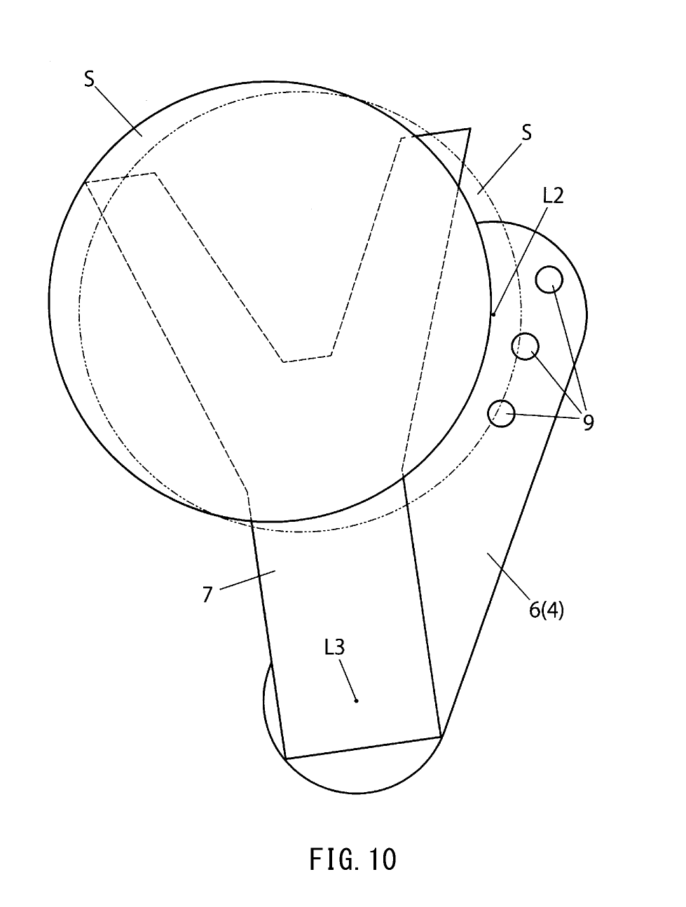

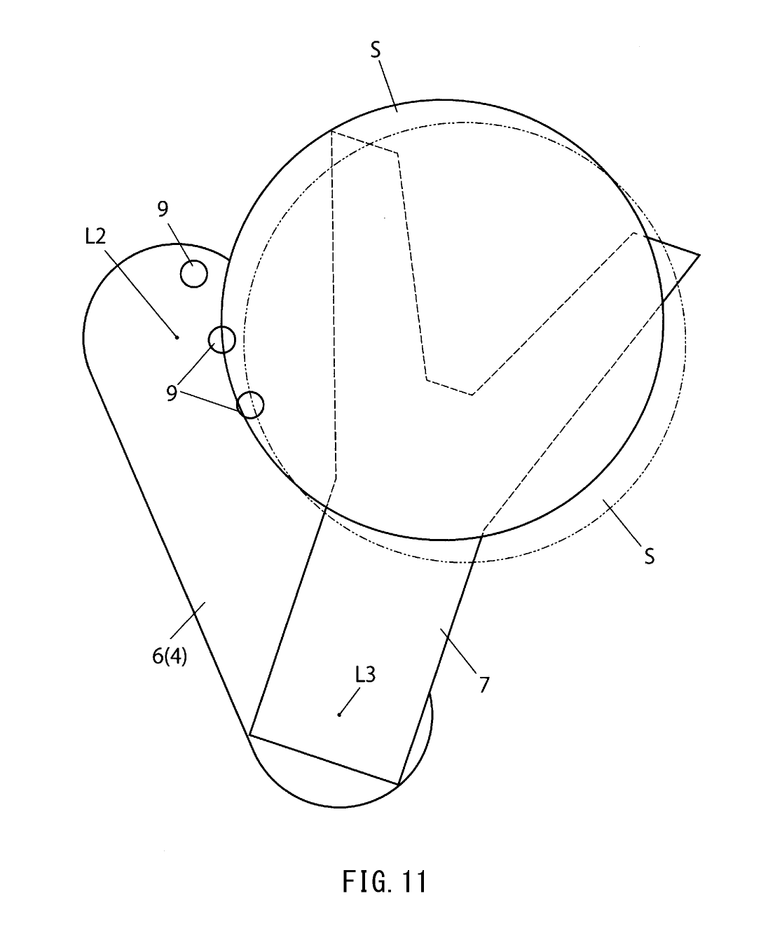

As a variation of the above embodiment, a plurality of (three in this example) substrate detection sensors 9 may be provided on the robot arm 4 as illustrated in FIG. 10 and FIG. 11. In this example, each of the above-mentioned hand rotation angles α′, β′ upon the front edge detection and rear edge detection can be acquired by the installation number of the substrate detection sensors 9. Therefore, the position of the substrate S on the hand 7 can be specified more surely and exactly.

Additionally, in this example wherein a plurality of detection sensors 9 are provided, two or more positions can be detected from only either one of the front edge and the rear edge in the moving direction of the substrate S. For example, when two positions of either one of the front edge and the rear edge in the moving direction of the substrate S are detected using the two detection sensors 9, the position of the substrate S on the hand 7 can be geometrically specified.

Note that, although a plurality of substrate detection sensors 9 are arranged in a row in parallel with the longitudinal axis of the second link member 6 in FIG. 10 and FIG. 11, arrangement of a plurality of substrate detection sensors 9 is not limited to this. The substrate detection sensors 9 may be arranged anywhere as long as the edge portion of the substrate S held by the hand 7 passes thereabove.

Additionally, although the substrate detection sensor 9 is arranged on the second link member 6 of the robot arm 4 in the above-mentioned embodiment and variation, arrangement of the substrate detection sensor 9 is not limited to this.

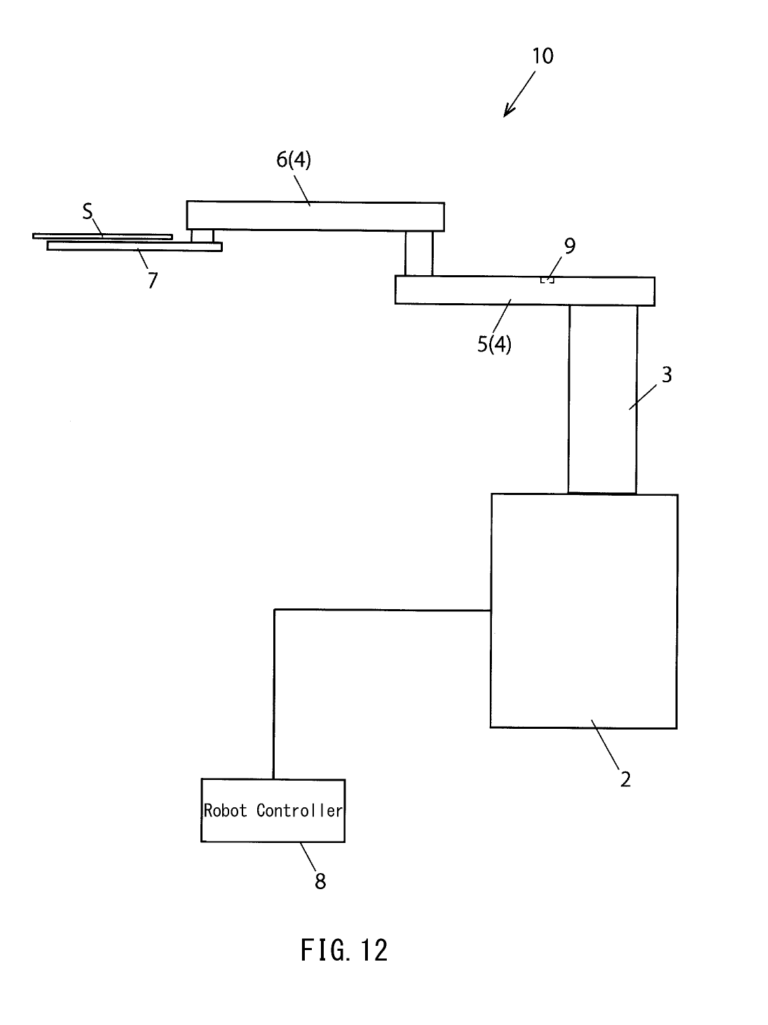

For example, in the substrate transfer robot 10 in FIG. 12, the robot arm 4 is configured such that the position of the hand 7 in the vertical direction is between the position of the first link member 5 and the second link member 6. In this configuration, in a normal substrate transfer operation of the robot arm 4, the substrate S held by the hand 7 passes above the first link member 5.

Accordingly, in this example, the substrate detection sensor 9 is installed on the upper surface of the first link member 5. Alternatively, the substrate detection sensor 9 may be installed on the lower surface of the second link member 6. Further, the substrate detection sensors 9 may be installed both on the upper surface of the first link member 5 and on the lower surface of the second link member 6.

As mentioned above, by the substrate transfer robots 1, 10 according to the above-mentioned embodiment and its variation, the position of the substrate on the hand can be specified using the substrate detection sensor (substrate detection unit) provided to the robot arm. Therefore, the substrate can be exactly transferred to a target position even when the substrate is deviated from the regular position on the hand.

Additionally, in the substrate transfer robots 1, 10 according to the above-mentioned embodiment and its variation, the installation position of the substrate detection sensor 9 is on the robot side. Therefore, the apparatus configuration required for detecting a substrate can be simplified.

Additionally, in the substrate transfer robots 1, 10 according to the above-mentioned embodiment and its variation, the position of the substrate S on the hand 7 can be specified during a normal substrate transfer operation. Therefore, a special robot operation for specifying the substrate position is not required. Accordingly, efficiency of the substrate transfer work is not declined by specifying the substrate position.

Additionally, in the substrate transfer robots 1, 10 according to the above-mentioned embodiment and its variation, two different parts of the edge portion of the substrate S are detected by the substrate detection sensor 9. Therefore, the position of the substrate S on the hand 7 can by specified by a geometric calculation based on the rotation angle α′, β′ upon detection of each point. Accordingly, the robot controller 8 can control the position of the hand 7 based on the actual position of the substrate S on the hand 7, and the substrate S can be exactly transferred to a target position.

### DESCRIPTION OF REFERENCE NUMERALS

1, 10 . . . substrate transfer robot

2 . . . base

3 . . . rotary spindle

4 . . . robot arm

5 . . . first link member

6 . . . second link member

7 . . . hand (substrate holding portion)

8 . . . robot controller (robot control unit)

9 . . . substrate detection sensor (substrate detection unit)

L1 . . . first rotational axis

L2 . . . second rotational axis

L3 . . . third rotational axis

S . . . substrate

1. A substrate transfer robot comprising:
a substrate holding portion for holding a substrate;
a robot arm to which the substrate holding portion is movably provided;
a robot control unit for controlling each operation of the robot arm and the substrate holding portion; and
a substrate detection unit provided to the robot arm and configured to detect an edge portion of the substrate held by the substrate holding portion,
wherein the substrate detection unit is configured to detect at least two parts of the edge portion of the substrate when the substrate holding portion holding the substrate is moved with respect to the robot arm, and
wherein the robot control unit is configured to correct a substrate transfer operation based on a detection result of the edge portion of the substrate by the substrate detection unit.

2. The substrate transfer robot according to claim 1,
wherein the robot arm has a first link member including a first rotational axis on a base end thereof and also including a second rotational axis on a distal end thereof, and a second link member including the second rotational axis on a base end thereof and also including a third rotational axis on a distal end thereof,
wherein the substrate holding portion is rotatable about the third rotational axis, and
wherein the substrate detection unit is provided to at least one of the first link member and the second link member.

3. The substrate transfer robot according to claim 1, wherein the substrate detection unit is provided to a surface of a link member configuring the robot arm.

4. The substrate transfer robot according to claim 1, wherein the substrate detection unit has a plurality of substrate detection sensors.

5. The substrate transfer robot according to claim 1, wherein the substrate detection unit is configured to detect the edge portion of the substrate during a normal transfer operation of the substrate.

6. The substrate transfer robot according to claim 1, wherein the substrate detection unit includes a reflection type light sensor.

7. A substrate transfer method using a substrate transfer robot having a robot arm to which a substrate holding portion for holding a substrate is movably provided, comprising:
a holding step of holding the substrate by the substrate holding portion;
a transfer step of transferring the substrate held by the substrate holding portion to a target position;
a detection step of detecting at least two parts of an edge portion of the substrate during the transfer step using a substrate detection unit provided to the robot arm; and
a correction step of correcting a substrate transfer operation based on a detection result of the edge portion of the substrate in the detection step.

8. The substrate transfer method according to claim 7, wherein, in the detection step, the edge portion of the substrate is detected during a rotational operation of the substrate holding portion with respect to the robot arm.

9. The substrate transfer method according to claim 7, wherein, in the detection step, the edge portion of the substrate is detected using the substrate detection unit provided to a surface of a link member configuring the robot arm.

10. The substrate transfer method according to claim 7, wherein, in the detection step, the edge portion of the substrate is detected using a reflection type light sensor configuring the substrate detection unit.
